(19) United States
(12) Patent Application Publication
(10) Pub. No.: US 2025/0309865 A1
(43) Pub. Date: Oct. 2, 2025

(54) OPTIMIZATION OF SAW FILTER SIZE, AREAL POWER DENSITY, AND SPURIOUS MODES VIA SAW RESONATOR METALIZATION RATIO AND FILTER TOPOLOGY AND ASSOCIATED SYSTEMS, DEVICES, AND METHODS

(71) Applicant: Qorvo US, Inc., Greensboro, NC (US)

(72) Inventors: Jason McGann, Tavares, FL (US); Jun Tsutsumi, Nishinomiya (JP)

(21) Appl. No.: 19/092,981

(22) Filed: Mar. 27, 2025

Related U.S. Application Data
(60) Provisional application No. 63/571,384, filed on Mar. 28, 2024.

(51) Int. Cl. H03H 9/72; H03H 9/25; H03H 9/64

(52) U.S. Cl. CPC H03H 9/725; H03H 9/25; H03H 9/6483

(57) ABSTRACT

Embodiments described herein provide systems, devices, and methods with optimized saw filter size, areal power density, and spurious modes. An acoustic wave device comprises: a piezoelectric substrate having a surface to support an acoustic wave; a first filter on the piezoelectric substrate, wherein the first filter comprises a first plurality of acoustic wave resonators, wherein the first plurality of acoustic wave resonators are associated with a first duty factors; and a second filter on the piezoelectric substrate and electrically connected to the first filter, wherein the second filter comprises a second plurality of acoustic wave resonators, wherein the second plurality of acoustic wave resonators are associated with a second duty factors, wherein a first resonator duty factor in the first duty factors or the second duty factors is configured to suppress a spurious mode within a first passband of the first filter or a second passband of the second filter.

### CROSS-REFERENCE TO RELATED APPLICATION

This application claims priority to U.S. Provisional Application No. 63/571,384 filed on Mar. 28, 2024, the benefit of which is claimed and the disclosure of which is incorporated herein in its entirety.

### TECHNICAL FIELD

The present disclosure relates generally to acoustic wave devices. In particular, to surface acoustic wave (SAW) filters with one or more SAW resonators whose area, spurious mode content, areal power density, and temperature coefficient of frequency, are optimized by adjusting the resonator metallization ratio independently for each SAW resonator comprising a SAW filter.

### BACKGROUND

A surface acoustic wave (SAW) resonator is a device that uses the mechanical vibrations of a piezoelectric material to filter and process electrical signals. SAW resonators are commonly used in electronic communication devices. SAW resonators are small, low-cost, and highly reliable resonators used for electronic filters which makes them ideal for use in compact electronic devices such as cellular phone RF filter multiplexers.

Ideally, SAW resonators have a single resonance frequency, known as the fundamental resonance frequency, and no higher order resonance frequencies, referred to herein as spurious mode content. Unfortunately, depending on the technology, several acoustic modes are excited in the resonator in addition to the fundamental resonance frequency, so called spurious modes. These additional modes often result in the presence of spurious content. In that regard, the resonator has high admittance not only at the fundamental resonance frequency but also at other frequencies. When the resonator is used in a filter, these extra modes can degrade the transfer function of the filter and potentially other filters electrically connected to the filter. In modern RF communication systems, it is now very common to use carrier aggregation, meaning that several bands are used at the same time. In this case, several filters or duplexers are connected to a single antenna node. If the spurious content of one filter is within the passband frequencies of a second filter, this spurious content will introduce extra losses to the second filter. It is very common for spurious content have a sharp and narrow band frequency response, meaning that the spurious content of the first filter may cause a very large ripple or notch in the passband of the second filter, causing signal degradation.

Some techniques have been utilized in an attempt to overcome this issue. As an example, external matching components may be added to a multiplexer circuit to suppress spurious content. However, this technique significantly increases cost and requires more space due to the extra components used. In addition, matching components may introduce their own extra loss to other parts of a multiplexer circuit. Also, varying resonator sizes and frequencies in a SAW transmit filter cause the areal power density (APD) to be different in each of the resonators comprising the filter. To meet power handling specifications for SAW transmit filters the resonators with high APD must be converted to 2× equivalent resonators in a series cascade configuration. In this series cascade configuration, the resonator area has increased by a factor of four while the APD is one quarter the original value. This result is very costly in terms of die size and does not act to balance the APD uniformly throughout the filter. Therefore, there is a need for techniques to reduce SAW filter size and improve APD within a filter.

### SUMMARY

Embodiments of the present disclosure include devices, systems, and methods for controlling SAW resonator areal power density and resonator area via saw resonator duty factor. Aspects of the disclosure advantageously provide SAW duplexers and multiplexers with selective alteration of the duty factor of SAW resonators contained in filters, duplexers, and multiplexers that preserve filter quality and improve areal power density.

In one general aspect, the present disclosure is directed to an acoustic wave device. The acoustic wave device also includes a piezoelectric substrate having a surface to support an acoustic wave; a first filter disposed on the piezoelectric substrate, where the first filter that may include a first plurality of acoustic wave resonators, where the first plurality of acoustic wave resonators are associated with a first one or more duty factors; and a second filter disposed on the piezoelectric substrate and electrically connected to the first filter, where the second filter that may include a second plurality of acoustic wave resonators, where the second plurality of acoustic wave resonators are associated with a second one or more duty factors, where a first resonator duty factor in the first one or more duty factors or the second one or more duty factors is configured to suppress a spurious mode associated with a frequency within a first passband of the first filter or a second passband of the second filter.

In some aspects, implementations may include one or more of the following features. The acoustic wave device where the first filter may include a transmission filter and the second filter may include a receiver filter, where a transmission passband of the transmission filter includes a first center frequency, where a receiver passband of the receiver filter includes a second center frequency, and where the first center frequency and second center frequency are different. The transmission filter is in a ladder configuration, where the first plurality of acoustic wave resonators includes a first plurality of shunt resonators and a first plurality of series resonators, and where the second plurality of acoustic wave resonators includes a second plurality of shunt resonators and a second plurality of series resonators. A duty factor of the first plurality of shunt resonators and the second plurality of shunt resonators is configured to minimize the spurious mode associated with the first plurality of shunt resonators and the second plurality of shunt resonators. A second resonator duty factor in the first one or more duty factors or the second one or more duty factors is configured to optimize the areal power density within the acoustic wave device. A third resonator duty factor in the first one or more duty factors or the second one or more duty factors is maximized. The first one or more duty factors that may include a first duty factor and a second duty factor, where the second one or more duty factors that may include a third duty factor and a fourth duty factor, where the first duty factor and the second duty factor are distinct, and where the third duty factor and fourth duty factor are distinct. The first resonator duty factor is between 40%-50%. A second resonator duty factor in the first one or more duty factors or the second one or more duty factors is between 80%-95%. At least one duty factor in the first one or more duty factors is distinct from each duty factor in the second one or more duty factors.

In one general aspect, the present disclosure is directed to a wireless communication device a radio frequency front end (RFFE) circuitry that may include: an acoustic wave device that may include: a piezoelectric substrate having a surface to support an acoustic wave; and a first filter disposed on the piezoelectric substrate, where the first filter that may include a first plurality of acoustic wave resonators, where the first plurality of acoustic wave resonators are associated with a first one or more duty factors; and a second filter disposed on the piezoelectric substrate and electrically connected to the first filter, where the second filter that may include a second plurality of acoustic wave resonators, where the second plurality of acoustic wave resonators are associated with a second one or more duty factors, where a first resonator duty factor in the first one or more duty factors or the second one or more duty factors is configured to suppress a spurious mode associated with a frequency within a first passband of the first filter or a second passband of the second filter.

In some aspects, implementations may include one or more of the following features. The wireless communication device where the first filter may include a transmission filter and the second filter that include a receiver filter, where a transmission passband of the transmission filter includes a first center frequency, where a receiver passband of the receiver filter includes a second center frequency, and where the first center frequency and second center frequency are different. The transmission filter is in a ladder configuration, where the first plurality of acoustic wave resonators includes a first plurality of shunt resonators and a first plurality of series resonators, and where the second plurality of acoustic wave resonators includes a second plurality of shunt resonators and a second plurality of series resonators. A duty factor of the first plurality of shunt resonators and the second plurality of shunt resonators is configured to minimize the spurious mode associated with the first plurality of shunt resonators and the second plurality of shunt resonators. A second resonator duty factor in the first one or more duty factors or the second one or more duty factors is configured to optimize the areal power density within the acoustic wave device. A third resonator duty factor in the first one or more duty factors or the second one or more duty factors is maximized. The first one or more duty factors that may include a first duty factor and a second duty factor, where the second one or more duty factors that may include a third duty factor and a fourth duty factor, where the first duty factor and the second duty factor are distinct, and where the third duty factor and fourth duty factor are distinct. The first resonator duty factor is between 40%-50%. A second resonator duty factor in the first one or more duty factors or the second one or more duty factors is between 80%-95%.

In one general aspect, the present disclosure is directed to a method performed by a wireless communication device. The method also includes generating, by the wireless communication device, a first signal for transmission. The method also includes filtering, by a first filter with a first passband of the wireless communication device, the first signal to suppress a spurious mode associated with a frequency within a second passband of a second filter of the wireless communication device. The method also includes transmitting, by an antenna of the wireless communication device, the filtered first signal. The method also includes receiving, by the antenna of the wireless communication device, a second signal. The method also includes filtering, by the second filter, the second signal. The method also includes where the first filter that may include a first plurality of acoustic wave resonators, where the first plurality of acoustic wave resonators are associated with a first one or more duty factors. The method also includes where the second filter is electrically connected to the first filter, where the second filter that may include a second plurality of acoustic wave resonators, where the second plurality of acoustic wave resonators are associated with a second one or more duty factors.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1A is a perspective view of a representative low-loss resonator technology surface acoustic wave (LRT-SAW) device, according to aspects of the present disclosure.

FIG. 1B is a perspective view of a representative temperature compensated surface acoustic wave (TC-SAW) device, according to aspects of the present disclosure.

FIG. 2 is a partial top view of a surface acoustic wave resonator with a first duty factor, according to aspects of the present disclosure.

FIG. 3 is a cross-sectional side view of the interdigital transducers of the surface acoustic wave resonator of FIG. 2, according to aspects of the present disclosure.

FIG. 4 is a partial top view of a surface acoustic wave resonator with a second duty factor, according to aspects of the present disclosure.

FIG. 5 is a cross-sectional side view of the interdigital transducers of surface acoustic wave resonator of FIG. 4, according to aspects of the present disclosure.

FIG. 6 is a graphical representation of the real admittance, according to aspects of the present disclosure.

FIG. 7 is a graphical representation of the power transmitted from the transmission port to the antenna, according to aspects of the present disclosure.

FIG. 8 is a schematic diagram of a surface acoustic wave duplexer in a first configuration, according to aspects of the present disclosure.

FIG. 9 is a schematic diagram of a surface acoustic wave duplexer in a second configuration, according to aspects of the present disclosure.

FIG. 10 is a schematic diagram of a surface acoustic wave duplexer in a third configuration, according to aspects of the present disclosure.

FIG. 11 is a schematic diagram of a surface acoustic wave duplexer in a fourth configuration, according to aspects of the present disclosure.

FIG. 12 is a schematic diagram of a surface acoustic wave duplexer in a fifth configuration, according to aspects of the present disclosure.

FIG. 13 is a schematic diagram of a surface acoustic wave duplexer in a sixth configuration, according to aspects of the present disclosure.

FIG. 14 is a graphical representation of a plurality of simulated attenuation functions, according to aspects of the present disclosure.

FIG. 15 is an illustration of acoustic area of a plurality of surface acoustic wave resonators, according to aspects of the present disclosure.

FIG. 16 is a block diagram of a wireless communication device including one or more SAW devices/filters, according to aspects of the present disclosure.

FIG. 17 is flow diagram of a method performed by a wireless communication device, according to some aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

As disclosed herein, the devices, systems and methods offer a number of improvements. Improved control of areal power density (APD) in a resonator can be achieved by adjusting the resonator duty factor (DF). Decreasing the resonator DF increases the area and reduces APD while increasing the resonator DF decreases the resonator area and increases APD. These combined adjustments to DF and area may have little impact on the measured SAW filter response. For resonators that are slightly too high in APD the resonator DF can be reduced, and the area increased. This approach avoids using a series cascade configuration that is very costly in terms of the filter die size. For resonators that are converted into a series cascade configuration increasing the resonator DF and reducing the area results in smaller resonators with higher APD that are still below the requirements. For temperature compensated resonators reducing DF typically improves the temperature coefficient of frequency which can also act to reduce APD by reducing frequency shifting under thermal loading.

As used herein, areal power density (APD) and distributed power density (DPD) may be used interchangeably, and duty factor (DF) and metallization ratio (MR) may be used interchangeably.

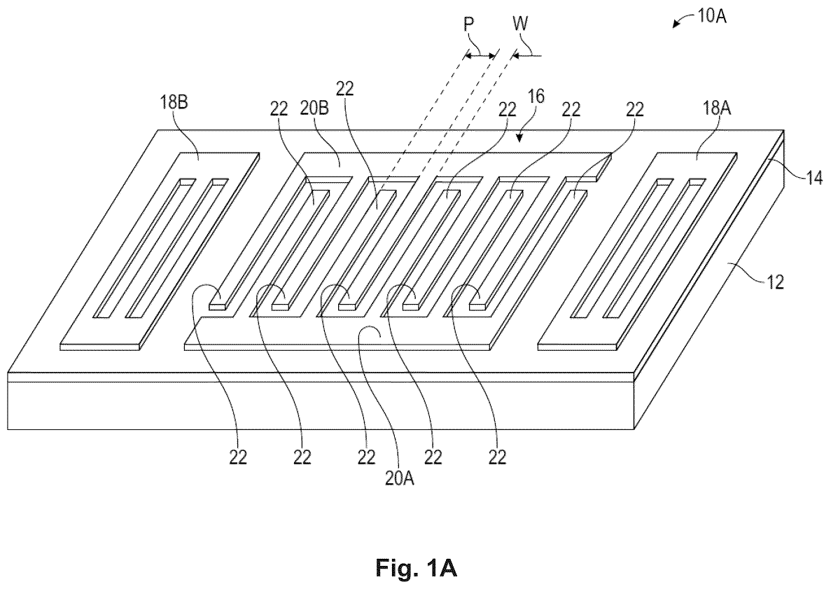

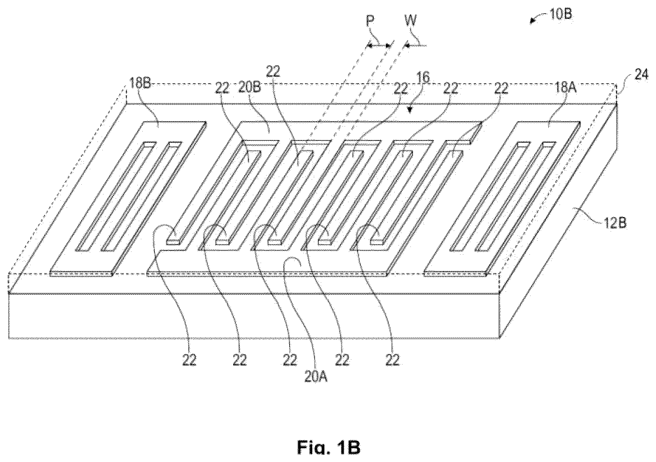

FIG. 1A is a perspective view of a representative low-loss resonator technology surface acoustic wave (LRT-SAW) device 10A. The LRT-SAW device 10A includes a substrate 12, a piezoelectric layer 14 on the substrate 12, an interdigital transducer (IDT) 16 including multiple electrodes 22 on a surface of the piezoelectric layer 14 opposite the substrate 12, a first reflector structure 18A on the surface of the piezoelectric layer 14 adjacent to the interdigital transducer 16, and a second reflector structure 18B on the surface of the piezoelectric layer 14 adjacent to the interdigital transducer 16 opposite the first reflector structure 18A. In certain aspects, the substrate 12 may be referred to as a carrier substrate and the LRT-SAW device 10A may be referred to as a guided SAW device. The layered substrate shown in FIG. 1A may comprise multiple layers. The piezoelectric layer 14 may also be referred to as a piezoelectric film and may be constructed of lithium tantalate or lithium niobate, or any other suitable material. The piezoelectric layer 14 may be bonded on the substrate 12, which may be referred to as a carrier substrate. It is understood that more than one film may be present, for example a silicon oxide film may be between the piezoelectric layer 14 and the carrier substrate 12.

The interdigital transducer 16 includes a first busbar 20A and a second busbar 20B, each of which may be connected to multiple electrodes 22 that are interleaved with one another as shown. The electrodes 22 may also be referred to as interdigitated electrodes. A lateral distance between adjacent electrodes 22 connected to the first busbar 20A and the second busbar 20B defines a pitch P between adjacent electrodes 22. The pitch P may at least partially define a resonant frequency of the corresponding electrodes 22. In that regard, in aspects in which the pitch P between electrodes 22 is uniform, all electrodes 22 may be configured to correspond to the same resonant frequency. This resonant frequency may be the resonant frequency of the LRT-SAW device 10A. A resonant frequency may be a frequency such that the mechanical waves excited between all the gaps between the electrodes are in phase. Resonant frequency can be adjusted by changing the velocity and/or pitch. An electrode 22 width W together with the pitch P may define a metallization ratio, or duty factor, of IDT 16. Pitch and duty factor can be the same or different for different electrodes 22 of the IDT 16.

In operation, an alternating electrical input signal provided at the first busbar 20A is transduced into a mechanical signal in the piezoelectric layer 14, resulting in one or more acoustic waves therein. In the case of the SAW device 10, the resulting acoustic waves are predominately surface acoustic waves. As discussed above, due to the pitch P and the metallization ratio of the IDT 16, the characteristics of the material of the piezoelectric layer 14, and other factors, the magnitude of the acoustic waves transduced in the piezoelectric layer 14 are dependent on the frequency of the alternating electrical input signal. This frequency dependence is often described in terms of changes in the impedance and/or a phase shift between the first busbar 20A and the second busbar 20B with respect to the frequency of the alternating electrical input signal. An alternating electrical potential between the two busbars 20A and 20B creates an electrical field in the piezoelectric material which generates acoustic waves. The acoustic waves travel at the surface and eventually are transferred back into an electrical signal between the busbars 20A and 20B. The first reflector structure 18A and the second reflector structure 18B reflect the acoustic waves in the piezoelectric layer 14 back towards the IDT 16 to confine the acoustic waves in the area surrounding the IDT 16.

The substrate 12 may comprise various materials including glass, sapphire, quartz, silicon (Si), silicon carbide (SiC), or gallium arsenide (GaAs) among others, with Si being a common choice. The piezoelectric layer 14 may be formed of any suitable piezoelectric material(s). In certain embodiments described herein, the piezoelectric layer 14 is formed of lithium tantalate (LT), or lithium niobate (LN), but is not limited thereto. In certain embodiments, the piezoelectric layer 14 is thick enough or rigid enough to function as a piezoelectric substrate. Accordingly, the substrate 12 in FIG. 1 may be omitted. Those skilled in the art will appreciate that the principles of the present disclosure may apply to other materials for the substrate 12 and the piezoelectric layer 14. The IDT 16, the first reflector structure 18A, and the second reflector structure 18B may comprise one or more of aluminum (Al), copper (Cu), titanium (Ti), platinum (Pt), tungsten (W), molybdenum (Mo) and alloys thereof in either single or multiple layer arrangements. While not shown to avoid obscuring the drawings, additional passivation layers, frequency trimming layers, or any other layers may be provided over all or a portion of the exposed surface of the piezoelectric layer 14, the IDT 16, the first reflector structure 18A, and the second reflector structure 18B. Such additional passivation layers may be provided for temperature compensation purposes and/or improved thermal conductivity, among other reasons. Further, one or more layers (such as silicon oxide) may be provided between the substrate 12 and the piezoelectric layer 14 in various embodiments. In some aspects, the thickness of the piezoelectric layer (e.g., layer 14) may be less than the acoustic wavelength. In aspects in which the piezoelectric layer 14 is formed of lithium niobate, the orientation of the piezoelectric layer 14 may be between Y+11 and Y+135. In other aspects in which the piezoelectric layer 14 is formed of lithium niobate, the orientation of the piezoelectric layer 14 may be between Y and Y+50. In aspects in which the piezoelectric layer 14 is formed of lithium tantalate, the orientation of the piezoelectric layer 14 may be between Y+50. The electrodes of the SAW device may be formed of any suitable material, including platinum, rhodium, palladium, iridium, conductive ceramics, or any other suitable material.

FIG. 1B is a perspective view of a representative temperature compensated surface acoustic wave (TC-SAW) device 10B. In some aspects, the TC-SAW device 10B may be substantially similar to the LRT-SAW device 10A of FIG. 1A. In some aspects, the IDT 16 may be positioned on a substrate 12B constructed of lithium niobate or lithium tantalate. Also, to reduce the temperature sensitivity of the device, the IDT 16 may be embedded in a dielectric film 24. The dielectric film 24 may be constructed of silicon oxide. In the case of the TC-SAW device 10B, plate modes resonating in the silicon oxide film 24 may exist at a frequency roughly 30% above the resonant frequency. Depending on the substrate and the films used (often called the stack), various spurious modes may also exist, linked for example to resonance in one of several of the films.

In some aspects, the dielectric film 24 may additionally be referred to as a dielectric material overcoat. In some aspects, the dielectric film 24 may be doped silicon oxide, for example, doped with fluorine.

In some embodiments, devices 10A and 10B may have additional piezoelectric layers. This disclosure is not limited to SAW devices. For example, the teachings of this disclosure may be applied to other devices that include IDT structures, e.g., bulk acoustic wave devices.

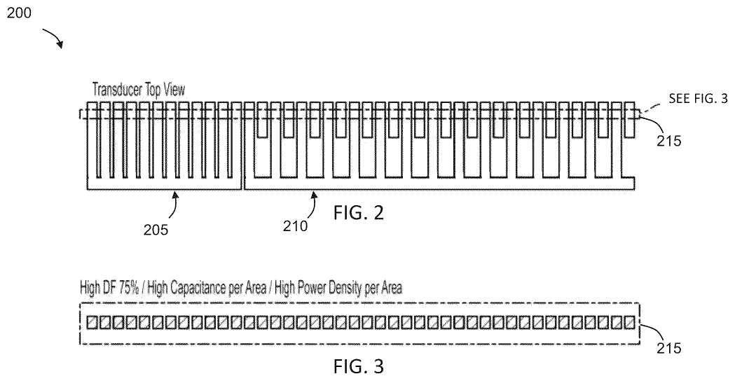

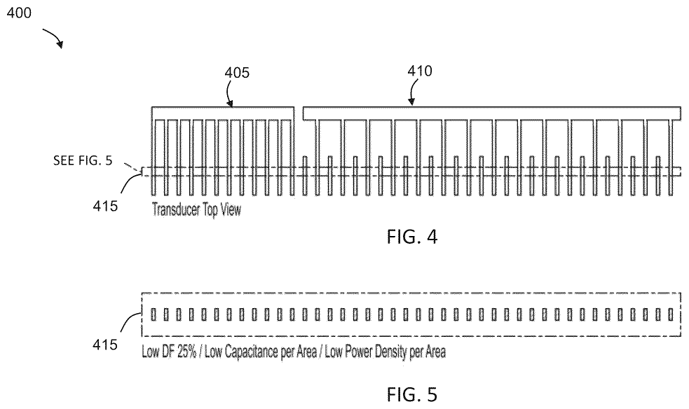

Referring to FIGS. 2-5, depicted therein are various views of SAW resonators with differing duty factors. FIGS. 2-3 depict a SAW resonator with a duty factor of approximately 0.75 (or 75%). FIGS. 4-5 depict a SAW resonator with a duty factor of approximately 0.25 (or 25%).

FIG. 2 is a partial top view of SAW resonator 200 with a first duty factor, according to aspects of the present disclosure. Saw resonator 200 includes a reflector 205 and interdigital transducer 210. As depicted in FIG. 2, SAW 200 has a duty factor, or metallization ratio of approximately 0.75 (or 75%). A cross section 215 is depicted in FIG. 3.

FIG. 3 is a cross-sectional side view of the interdigital transducers of the surface acoustic wave resonator of FIG. 2, according to aspects of the present disclosure. Because of the relatively tight spacing of the individual transducers, the capacitance per area and power density is high.

FIG. 4 is a partial top view of SAW resonator 400 with a second duty factor, according to aspects of the present disclosure. SAW resonator 200 includes a reflector 405 and interdigital transducer 410. As depicted in FIG. 4, SAW resonator has a duty factor, or metallization ratio, of approximate 0.25 (or 25%). A cross section 415 is depicted in FIG. 5.

FIG. 5 is a cross-sectional side view of the interdigital transducers of surface acoustic wave resonator of FIG. 4, according to aspects of the present disclosure. The spacing and width of the transducers in resonator 400 is larger and smaller than resonator 200, respectively. Thus, relative to SAW resonator 200, resonator 400 has a lower capacitance per area and lower power density.

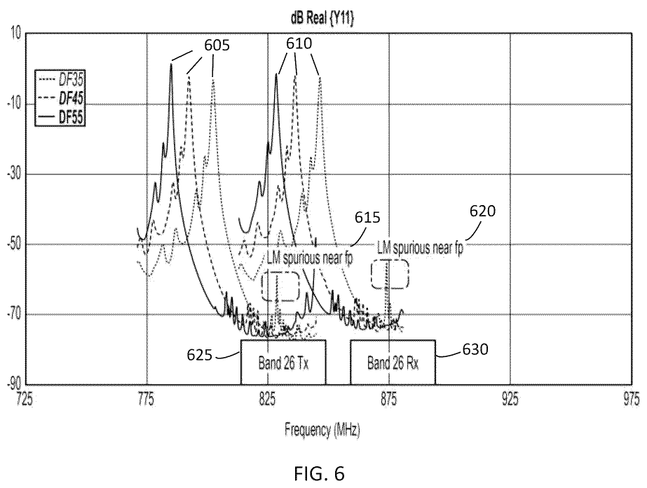

FIG. 6 is a graphical representation of the real admittance, according to aspects of the present disclosure. Shunt resonators curves 605 depict the real admittance of shunt resonators of varying duty factors across a frequency range from approximately 770 MHz to 850 MHz. Series resonator curves 610 depict the real admittance of series resonators of varying duty factors across a frequency range from approximately 810 MHz to 890 MHz. DF35, DF40, and DF55 refer to curves with a duty factor of 35%, 40%, and 55%, respectively. A shunt resonator with a duty factor of 35% possesses a spurious mode 615 at frequencies within the transmission band 625, as shown in FIG. 2. A series resonator with a duty of 35% possesses a spurious mode 620 at frequencies within the receiver band 630, as shown in FIG. 2. An advantage of some embodiments described herein is the reduction of the impact of spurious modes on device performance.

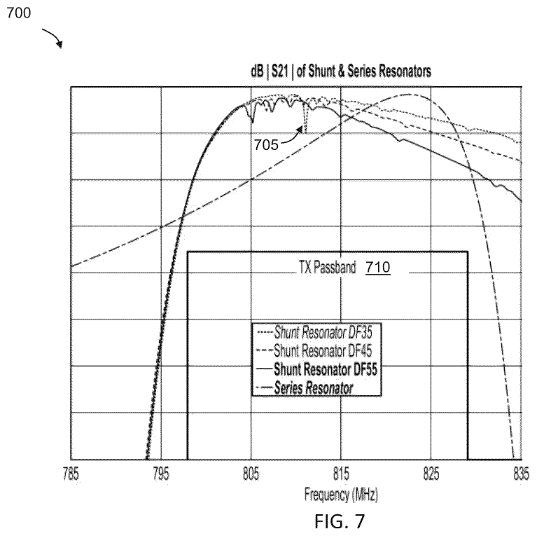

FIG. 7 is a graphical representation of the gain from the transmission port to the antenna for various resonators, according to aspects of the present disclosure. Graph 700 depicts the gain for three shunt resonators with different duty factors and a series resonator. The influence 705 of spurious modes can be seen in the gain for the shunt resonators. Because that influence 705 from spurious modes occurs in the transmission band 710, it may be minimized by an appropriate choice for the duty factor. For example, the spurious mode minimizing duty factor for the shunt resonators may be 45% in the example shown in FIG. 7.

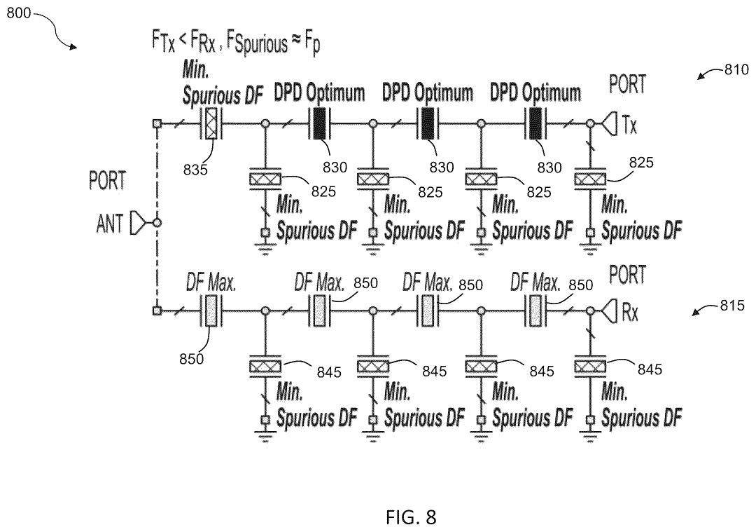

Referring to FIGS. 8-12, depicted therein are different configurations of the surface acoustic wave duplexers, according to aspects. Each configuration selectively chooses the duty factor to meet various constraints on duplexer devices. For example, APD may be a concern for the transmission filter but not the receiver filter. In another example, the duty factor of the resonator closest to the antenna may be chosen to prevent spurious content from the transmit filter to induce losses in the passband of the receive filter. It should be appreciated that similar configurations and selections for series and shunt SAW resonators in duplexers are applicable in a multiplexer configuration. A multiplexer may have multiple transmission and/or receiver filters (e.g., similar to 810, 910, 1010, 1110, 1210, 1310 and/or 815, 915, 1015, 1115, 1215, respectively) connected to an antenna port. Furthermore, fewer or more shunt and series resonators may be incorporated into the transmission and receiver filters described below. In some embodiments, that may include series cascade configurations of two or more series resonators. The filters described herein may be disposed on a piezoelectric substrate. As described herein, duty factors may range from 1% to 99%. For example, a SAW resonator may have a duty factor of 60%-99% when it has been optimized for size and a duty factor of 1%-60% when it has been optimized to reduce spurious modes.

SAW resonator-based duplexers, and multiplexers more generally, can span resonance frequencies from 400 MHz up to 8 GHz+. Anti-resonance frequencies, Fₚ, can be expressed in terms of resonant frequencies and are typically Fₚ<1.3 Fₛ. Spurious mode Fₛₚᵤᵣᵢₒᵤₛ frequencies addressed by this approach are those that lie near the acoustic bands typically in the range Fₛ−2(Fₚ−Fₛ) to Fₚ+2(Fₚ−Fₛ).

FIG. 8 is a schematic diagram of a surface acoustic wave duplexer 800 in a first configuration, according to aspects of the present disclosure. The duplexer 800 is configured to transmit and receive signals, wherein the transmission passband frequencies are less than the receiver passband frequencies. The first configuration of the duplexer 800 is chosen to minimize the impacts of spurious modes occurring around a frequency Fₛₚᵤᵣᵢₒᵤₛ near the anti-resonance frequency, Fₚ. Duplexer 800 may include an antenna port, transmission filter 810, and receiver filter 815.

Transmission filter 810 may act as a filter for signals originating from the transmission port. As depicted in FIG. 8, filter 810 may be in a ladder configuration. In duplexer 800, the transmission filter has a transmission passband whose center frequency is less than the center frequency of the receiver filter 815. Transmission filter 810 may include a transmission port/terminal, shunt resonators 825, series resonators 830, 835.

The shunt resonators 825 and series resonators 830, 835 may be electrically connected to one other to form a ladder network. The resonators 825, 830, 835 may be designed in such a way that the resonance frequency of the series resonators and the anti-resonance frequency of the shunt resonators are close to the center of a passband for the transmission filter. Because the series resonators may be electrically equivalent to a short circuit at the center frequency of the passband of the transmission filter, and the shunt resonators may be equivalent to an open circuit at the center frequency of the passband, the transmission filter may have relatively low losses in the passband. Inversely, at its resonance frequency the shunt resonators may be equivalent to a short circuit, which may cause a notch in the filter transfer function of the transmission filter. Similarly, at its anti-resonance frequency the series resonators may be equivalent to an open circuit, which may also result in a notch in the filter transfer function of the transmission filter. Similar observations apply for the resonators of the receiver filter 815.

Series resonators 830, 835 may be surface acoustic wave resonators as depicted in, and described with respect to, FIGS. 1-5. The duty factors of the series resonators 830, 835 in duplexer 800 are selected based on different objectives. Series resonators 830 have a duty factor which is determined to optimize the distributed power density of each of the resonators. Series resonator 835 is configured to have a duty factor that minimize spurious modes. DF of the series resonator 835 is selected to minimize the conductance of spurious modes in the Rx band that load the Rx filter. Series resonator 835 is the resonator in proximity to, or closest to, the antenna port, making it a good choice for optimizing the duty factor to remove spurious mode contributions. In some instances, the spurious mode frequencies lay in the receiver passband and therefore can cause loss in receiver filter to a receiver port, if not suppressed in the transmission filter 810.

Shunt resonators 825 may be surface acoustic wave resonators as depicted in, and described with respect to, FIGS. 1-5. Duplexer 800 comprises a single duty factor for the shunt resonators 825. The duty factor of the shunt resonators 825 may be selected to minimize the spurious modes within the transmission passband. Because the anti-resonance frequency of shunt resonators is within the transmission passband, spurious modes near the anti-resonance frequency are also within or close to the transmission passband.

Receiver filter may act as a filter for signals generated and/or received at the antenna. Filter 815 may be in a ladder configuration. In duplexer 800, the receiver filter has a receiver passband whose center frequency is greater than the center frequency of the transmission filter. Receiver filter 810 may include a receiver port, shunt resonators 845, series resonators 850.

Series resonators 850 may be surface acoustic wave resonators as depicted in, and described with respect to, FIGS. 1-5. Duplexer 800 comprises one configuration for the series resonators 850. Series resonators 850 have a duty factor which may be maximized because the receiver filter does not have the power handling constraints of the transmission filter 810. Furthermore, each of the series resonators 850 in the receiver filter 815 may have the same duty factor because the spurious modes arising near the anti-resonance frequency of the series resonator lay outside the receiver passband at higher frequencies.

Shunt resonators 845 may be surface acoustic wave resonators as depicted in, and described with respect to, FIGS. 1-5. Duplexer 800 comprises a single duty factor for the shunt resonators 845. The duty factor of the shunt resonators 845 may be selected to minimize spurious modes within the receiver passband. Because the anti-resonance frequency of shunt resonators is within the receiver passband, spurious modes near the anti-resonance frequency are also within or close to the receiver passband.

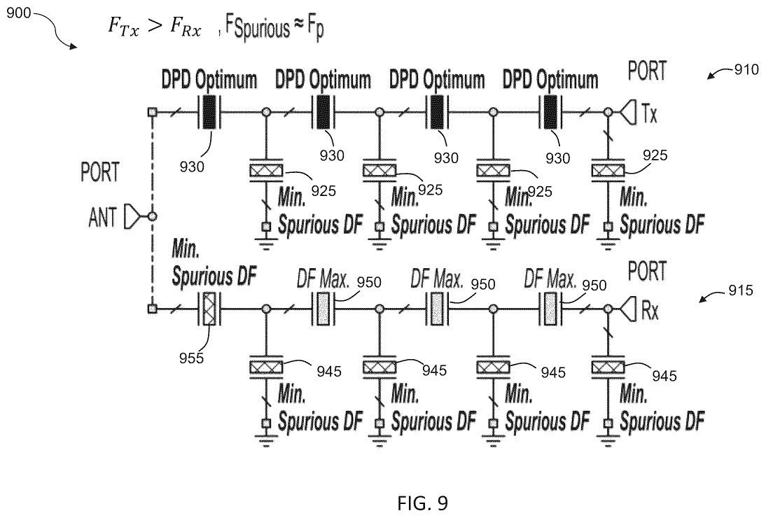

FIG. 9 is a schematic diagram of a surface acoustic wave duplexer 900 in a second configuration, according to aspects of the present disclosure. The duplexer 900 is configured to transmit and receive signals, wherein the transmission passband frequencies are greater than the receiver passband frequencies. The second configuration of the duplexer 900 is chosen to minimize the impacts of spurious modes occurring around a frequency Fₛₚᵤᵣᵢₒᵤₛ near the anti-resonance frequency, Fₚ. Duplexer 900 may include an antenna port, transmission filter 910, and receiver filter 915.

Transmission filter 910 may act as a filter for signals originating from the transmission port. As depicted in FIG. 9, filter 910 may be in a ladder configuration. In duplexer 900, the transmission filter has a transmission passband whose center frequency is greater than the center frequency of the receiver filter 915. Transmission filter 910 may include a transmission port/terminal, shunt resonators 925, series resonators 930.

The shunt resonators 925 and series resonators 930 may be electrically connected to one other to form a ladder network. The resonators 925, 830 may be designed in such a way that the resonance frequency of the series resonators and the anti-resonance frequency of the shunt resonators are close to the center of a passband for the transmission filter. Because the series resonators may be electrically equivalent to a short circuit at the center frequency of the passband of the transmission filter, and the shunt resonators may be equivalent to an open circuit at the center frequency of the passband, the transmission filter may have relatively low losses in the passband. Inversely, at its resonance frequency the shunt resonators may be equivalent to a short circuit, which may cause a notch in the filter transfer function of the transmission filter. Similarly, at its anti-resonance frequency the series resonators may be equivalent to an open circuit, which may also result in a notch in the filter transfer function of the transmission filter. Similar observations apply for the resonators of the receiver filter 915.

Series resonators 930 may be surface acoustic wave resonators as depicted in, and described with respect to, FIGS. 1-5. Series resonators 930 have a duty factor which is determined to optimize the distributed power density of each of the resonators. In this configuration, contribution of spurious modes well above the receiver passband may be allowed through the transmission filter.

Shunt resonators 925 may be surface acoustic wave resonators as depicted in, and described with respect to, FIGS. 1-5. Duplexer 900 comprises a single duty factor for the shunt resonators 925. The duty factor of the shunt resonators 925 may be selected to minimize the spurious modes within the transmission passband. Because the anti-resonance frequency of shunt resonators is within the transmission passband, spurious modes near the anti-resonance frequency are also within or close to the transmission passband. Therefore, shunt resonators 925 may have their duty factor optimized to minimize spurious contributions.

Receiver filter may act as a filter for signals generated and/or received at an antenna. Filter 915 may be in a ladder configuration. In duplexer 900, the receiver filter 915 has a receiver passband whose center frequency is greater than the center frequency of the transmission filter. Receiver filter 915 may include a receiver port, shunt resonators 945, series resonators 950, 955.

Series resonators 950, 955 may be surface acoustic wave resonators as depicted in, and described with respect to, FIGS. 1-5. Duplexer 900 comprises two configurations for the series resonators 950, 955. Series resonators 950 have a duty factor which may be maximized because the receiver filter does not have the power handling constraints of the transmission filter 910. Series resonator 955 may have a duty factor to minimize spurious mode contributions.

Shunt resonators 945 may be surface acoustic wave resonators as depicted in, and described with respect to, FIGS. 1-5. Duplexer 900 comprises a single duty factor for the shunt resonators 945. The duty factor of the shunt resonators 945 may be selected to minimize spurious modes with the receiver passband. Because the anti-resonance frequency of shunt resonators is within the receiver passband, spurious modes near the anti-resonance frequency are also within or close to the receiver passband.

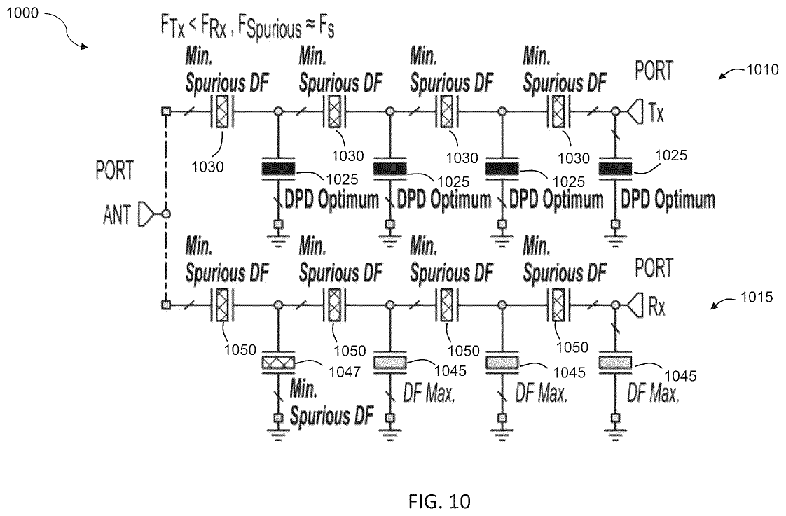

FIG. 10 is a schematic diagram of a surface acoustic wave duplexer in a third configuration, according to aspects of the present disclosure. The duplexer 1000 is configured to transmit and receive signals, wherein the transmission passband frequencies are less than the receiver passband frequencies. The third configuration of the duplexer 1000 is chosen to minimize the impacts of spurious modes occurring around a frequency Fₛₚᵤᵣᵢₒᵤₛ near the resonance frequency, Fₛ. Duplexer 1000 may include an antenna port, transmission filter 1010, and receiver filter 1015.

Transmission filter 1010 may act as a filter for signals originating from the transmission port. As depicted in FIG. 10, filter 1010 may be in a ladder configuration. In duplexer 1000, the transmission filter has a transmission passband whose center frequency is less than the center frequency of the receiver filter 1015. Transmission filter 1010 may include a transmission port/terminal, shunt resonators 1025, series resonators 1030.

The shunt resonators 1025 and series resonators 1030 may be electrically connected to one other to form a ladder network. The resonators 1025, 1030, may be designed in such a way that the resonance frequency of the series resonators and the anti-resonance frequency of the shunt resonators are close to the center of a passband for the transmission filter. Because the series resonators may be electrically equivalent to a short circuit at the center frequency of the passband of the transmission filter, and the shunt resonators may be equivalent to an open circuit at the center frequency of the passband, the transmission filter may have relatively low losses in the passband. Inversely, at its resonance frequency the shunt resonators may be equivalent to a short circuit, which may cause a notch in the filter transfer function of the transmission filter. Similarly, at its anti-resonance frequency the series resonators may be equivalent to an open circuit, which may also result in a notch in the filter transfer function of the transmission filter. Similar observations apply for the resonators of the receiver filter 1015.

Series resonators 1030 may be surface acoustic wave resonators as depicted in, and described with respect to, FIGS. 1-5. Duplexer 1000 comprises a single duty factor for the series resonators. Series resonators 1030 have a duty factor which is determined to minimize the contributions from spurious modes. In some instances, the spurious mode frequencies lay in the transmission passband and therefore should be minimized to preserve transmission filter performance.

Shunt resonators 1025 may be surface acoustic wave resonators as depicted in, and described with respect to, FIGS. 1-5. Duplexer 1000 comprises a single duty factor for the shunt resonators 1025. The duty factor of the shunt resonators 1025 may be selected to optimize the areal power density. Because the resonance frequency of shunt resonators sits at frequencies below the transmission passband, spurious mode contributions do not interfere with the performance of the transmission filter 1010. Nor do they interfere with the receiver filter 1015 because the receiver passband lays at higher frequencies to the transmission passband.

Receiver filter 1015 may act as a filter for signals generated and/or received at the antenna. Filter 1015 may be in a ladder configuration. In duplexer 1000, the receiver filter 1015 has a receiver passband whose center frequency is greater than the center frequency of the transmission passband. Receiver filter 1010 may include a receiver port, shunt resonators 1045, 1047, and series resonators 1050.

Series resonators 1050 may be surface acoustic wave resonators as depicted in, and described with respect to, FIGS. 1-5. Duplexer 1000 comprises a single duty factor for the series resonators 1050. Series resonators 1050 have a duty factor which may be selected to minimize the contributions from spurious modes. Furthermore, each of the series resonators 1050 in the receiver filter 815 may have the same duty factor because the spurious modes arising near the resonance frequency of the series resonator sit within the receiver passband.

Shunt resonators 1045, 1047 may be surface acoustic wave resonators as depicted in, and described with respect to, FIGS. 1-5. Duplexer 1000 comprises two duty factors for the shunt resonators 1045, 1047. The duty factor of the shunt resonators 1045 may be selected to maximize the duty fact since the receiver filter 1015 does not have the power handling requirements of the transmission filter 1010. The duty factor of the shunt resonator 1047 may be chosen to minimize the contributions from spurious modes. Because the resonance frequency of shunt resonators is within or near the transmission band, spurious modes near fs in 1047 may cause loss in filter 1010.

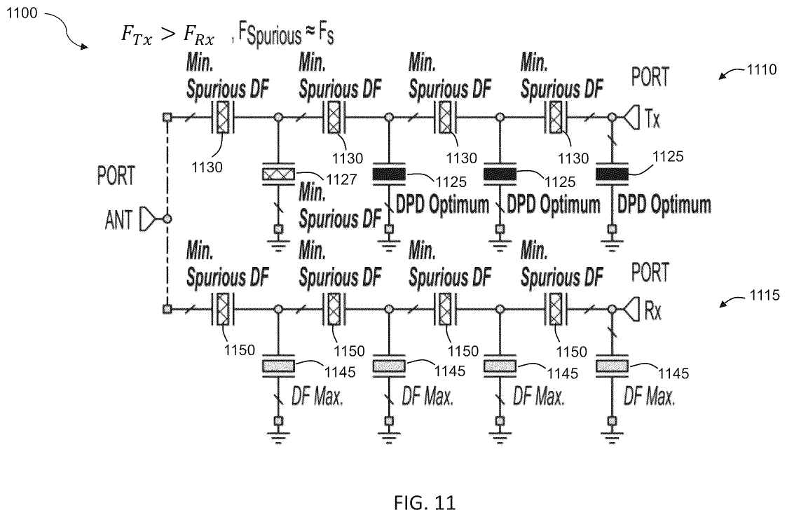

FIG. 11 is a schematic diagram of a surface acoustic wave duplexer in a fourth configuration, according to aspects of the present disclosure. The duplexer 1100 is configured to transmit and receive signals, wherein the transmission passband frequencies are less than the receiver passband frequencies. The fourth configuration of the duplexer 1100 is chosen to minimize the impacts of spurious modes occurring around a frequency Fₛₚᵤᵣᵢₒᵤₛ near the resonance frequency, Fₛ. Duplexer 1100 may include an antenna port, transmission filter 1110, and receiver filter 1115.

Transmission filter 1110 may act as a filter for signals originating from the transmission port. As depicted in FIG. 11, filter 1110 may be in a ladder configuration. In duplexer 1100, the transmission filter has a transmission passband whose center frequency is less than the center frequency of the receiver filter 1115. Transmission filter 1110 may include a transmission port/terminal, shunt resonators 1125, 1127 series resonators 1130.

The shunt resonators 1125, 1127 and series resonators 1130 may be electrically connected to one another to form a ladder network. The resonators 1125, 1127, 1130 may be designed in such a way that the resonance frequency of the series resonators and the anti-resonance frequency of the shunt resonators are close to the center of a passband for the transmission filter. Because the series resonators may be electrically equivalent to a short circuit at the center frequency of the passband of the transmission filter, and the shunt resonators may be equivalent to an open circuit at the center frequency of the passband, the transmission filter may have relatively low losses in the passband. Inversely, at its resonance frequency the shunt resonators may be equivalent to a short circuit, which may cause a notch in the filter transfer function of the transmission filter. Similarly, at its anti-resonance frequency the series resonators may be equivalent to an open circuit, which may also result in a notch in the filter transfer function of the transmission filter. Similar observations apply for the resonators of the receiver filter 1115.

Series resonators 1130 may be surface acoustic wave resonators as depicted in, and described with respect to, FIGS. 1-5. Duplexer 1100 comprises one duty factors for the series resonators. Series resonators 1130 have a duty factor which is selected to minimize the contributions from spurious modes. Because the resonance frequency of series resonators 1130 sits within the transmission passband so do the contributions from spurious modes near the resonance frequency. Thus, contributions from spurious modes may be minimized.

Shunt resonators 1125, 1127 may be surface acoustic wave resonators as depicted in, and described with respect to, FIGS. 1-5. Duplexer 1100 comprises two duty factors for the shunt resonators 1125, 1127. The duty factor of the shunt resonators 1125 may be selected to optimize the distributed power density, whereas duty factor of the shunt resonator 1127 may be selected to minimize spurious mode contributions.

Receiver filter 1115 may act as a filter for signals generated and/or received at the antenna. Filter 1115 may be in a ladder configuration. In duplexer 1100, the receiver filter has a receiver passband whose center frequency is greater than the center frequency of the transmission filter. Receiver filter 1110 may include a receiver port, shunt resonators 1145, series resonators 1150.

Series resonators 1150 may be surface acoustic wave resonators as depicted in, and described with respect to, FIGS. 1-5. Duplexer 1100 comprises one configuration for the series resonators 1150. Series resonators 1150 have a duty factor which may be selected to minimize the contributions from spurious modes. Because the resonance frequency of series resonators 1150 sits within the receiver passband so do the contributions from spurious modes near the resonance frequency. Thus, contributions from spurious modes may be minimized.

Shunt resonators 1145 may be surface acoustic wave resonators as depicted in, and described with respect to, FIGS. 1-5. Duplexer 1100 comprises a single duty factor for the shunt resonators 1145. The duty factor of the shunt resonators 1145 may be maximized because the receiver filter does not have the power handling that the transmission filter does.

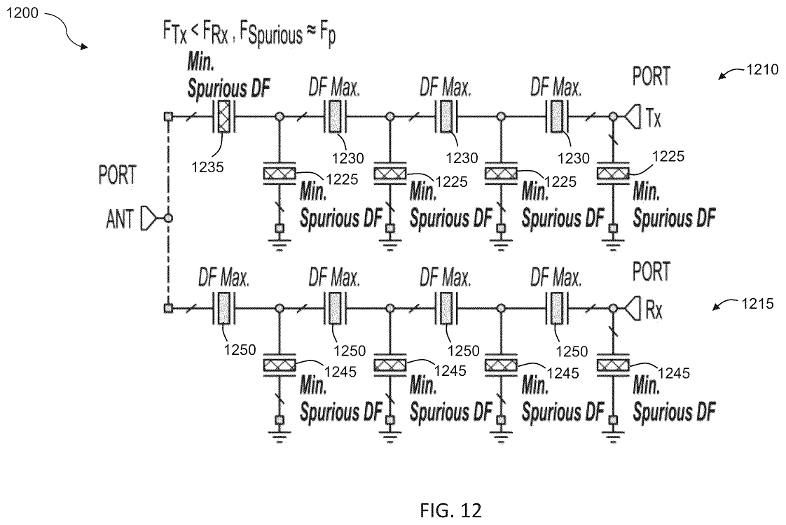

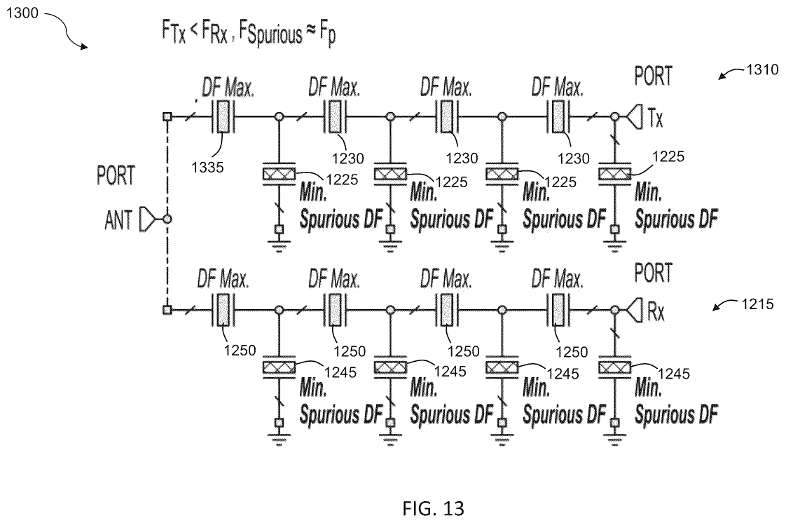

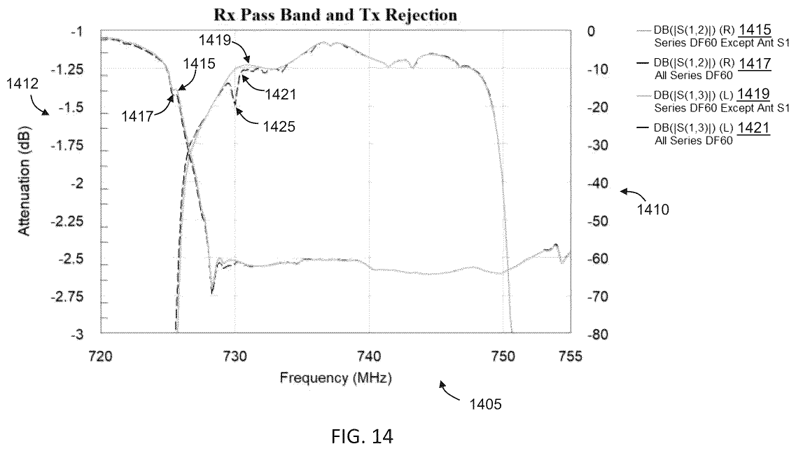

Referring to FIGS. 12-14, two additional configurations of duplexer are depicted along with attenuation results for comparison. The simulated performance of the duplexer configurations of FIGS. 12-13 are compared in FIG. 14. FIG. 13 depicts the nominal configuration, whereas FIG. 12 is configured according to aspects of the disclosure described herein.

FIG. 12 is a schematic diagram of a surface acoustic wave duplexer in a fifth configuration, according to aspects of the present disclosure. The duplexer 1200 is configured to transmit and receive signals, wherein the transmission passband frequencies are less than the receiver passband frequencies. The fifth configuration of the duplexer 1200 is chosen to minimize the impacts of spurious modes occurring around a frequency Fₛₚᵤᵣᵢₒᵤₛ near the anti-resonance frequency, Fₚ. Duplexer 1200 may include an antenna port, transmission filter 1210, and receiver filter 1215. Duplexer 1200 is the same as Duplexer 800 aside from series resonators 830 have a duty factor optimized for areal power density and series resonators 1230 have maximized duty factors.

Transmission filter 1210 may act as a filter for signals originating from the transmission port. As depicted in FIG. 12, filter 1210 may be in a ladder configuration. In duplexer 1200, the transmission filter has a transmission passband whose center frequency is less than the center frequency of the receiver filter 1215. Transmission filter 1210 may include a transmission port/terminal, shunt resonators 1225, series resonators 1230, 1235.

The shunt resonators 1225 and series resonators 1230, 1235 may be electrically connected to one another to form a ladder network. The resonators 1225, 1230, 1235 may be designed in such a way that the resonance frequency of the series resonators and the anti-resonance frequency of the shunt resonators are close to the center of a passband for the transmission filter. Because the series resonators may be electrically equivalent to a short circuit at the center frequency of the passband of the transmission filter, and the shunt resonators may be equivalent to an open circuit at the center frequency of the passband, the transmission filter may have relatively low losses in the passband. Inversely, at its resonance frequency the shunt resonators may be equivalent to a short circuit, which may cause a notch in the filter transfer function of the transmission filter. Similarly, at its anti-resonance frequency the series resonators may be equivalent to an open circuit, which may also result in a notch in the filter transfer function of the transmission filter. Similar observations apply for the resonators of the receiver filter 1215.

Series resonators 1230, 1235 may be surface acoustic wave resonators as depicted in, and described with respect to, FIGS. 1-5. The duty factors of the series resonators 1230, 1235 in duplexer 1200 are selected based on different objectives. Series resonators 1230 have a duty factor which is maximized. Series resonator 1235 is configured to have a duty factor that minimizes spurious modes. Series resonator 1235 minimizes spurious modes transmitted by the series resonators 1230 of the transmission filter 1210 so that signal from the transmission does not leak into the receiver filter 1215. Series resonator is the resonator in proximity to, or closest to, the antenna port, making it a good choice for optimizing the duty factor to remove spurious mode contributions. In some instances, the spurious mode frequencies lay in the receiver passband and therefore can pass through the receiver filter to the receiver port 1240, if not suppressed in the transmission filter 1210.

Shunt resonators 1225 may be surface acoustic wave resonators as depicted in, and described with respect to, FIGS. 1-5. Duplexer 1200 comprises a single duty factor for the shunt resonators 1225. The duty factor of the shunt resonators 1225 may be selected to minimize the spurious modes within the transmission passband. Because the anti-resonance frequency of shunt resonators is within the transmission passband, spurious modes near the anti-resonance frequency are also within or close to the transmission passband.

Receiver filter 1215 may act as a filter for signals generated and/or received at the antenna. Filter 1215 may be in a ladder configuration. In duplexer 1200, the receiver filter has a receiver passband whose center frequency is greater than the center frequency of the transmission filter. Receiver filter 1210 may include a receiver port, shunt resonators 1245, series resonators 1250.

Series resonators 1250 may be surface acoustic wave resonators as depicted in, and described with respect to, FIGS. 1-5. Duplexer 1200 comprises one configuration for the series resonators 1250. Series resonators 1250 have a duty factor which may be maximized because the receiver filter does not have the power handling constraints of the transmission filter 1210. Furthermore, each of the series resonators 1250 in the receiver filter 1215 may have the same duty factor because the spurious modes arising near the anti-resonance frequency of the series resonator lay outside the receiver passband at higher frequencies.

Shunt resonators 1245 may be surface acoustic wave resonators as depicted in, and described with respect to, FIGS. 1-5. Duplexer 1200 comprises a single duty factor for the shunt resonators 1245. The duty factor of the shunt resonators 1245 may be selected to minimize spurious modes with the receiver passband. Because the anti-resonance frequency of shunt resonators is within the receiver passband, spurious modes near the anti-resonance frequency are also within or close to the receiver passband.

FIG. 13 is a schematic diagram of a surface acoustic wave duplexer in a sixth configuration, according to aspects of the present disclosure. The duplexer 1300 is configured to transmit and receive signals, wherein the transmission passband frequencies are less than the receiver passband frequencies. The sixth configuration of the duplexer serves as a comparison to duplexer 1200. The only difference between duplexer 1300 and 1200 is series resonator 1235 has been replaced with series resonator 1335 with a maximum duty factor in the transmission filter 1310.

FIG. 14 is a graphical representation of a plurality of simulated attenuation functions for the receiver pass band and a portion of the transmission rejection, according to aspects of the present disclosure. Graph 1400 has vertical axes 1410, 1412 representing attenuation in units of dB and a horizontal axis representing frequency in units of MHz. Transmission attenuation functions 1415, 1417 are read against the vertical axis 1410, whereas receiver attenuation functions 1419, 1421 are read against vertical axis 1412. In the receiver band, from approximately 728 MHz to 746 MHz, a notch 1425 in the receiver attenuation function 1421 depicts the effect of spurious modes. Transmission attenuation functions 1415A and receiver attenuation function 1420A correspond to behavior of the duplexer 1200. Transmission attenuation functions 1415C and receiver attenuation function 1420C correspond to behavior of the duplexer 1300.

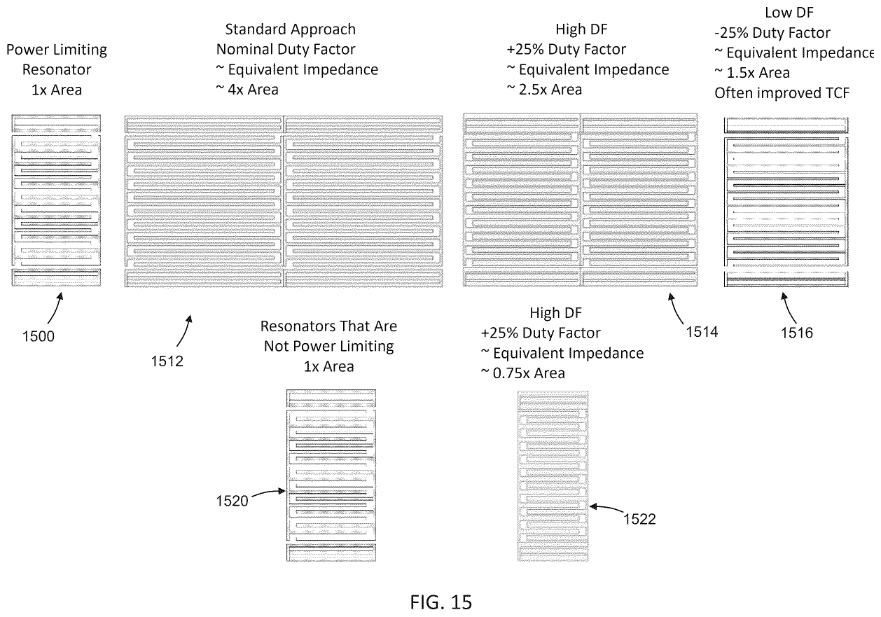

FIG. 15 is an illustration of acoustic area of a plurality of surface acoustic wave resonators, according to aspects of the present disclosure. For sake of comparison, SAW resonators 1512, 1514, 1516, 1522 have equivalent impedance. Surface acoustic wave resonator 1500 provides a reference area and nominal duty factor for comparison with other power-limiting resonators. In the standard approach to reducing the areal power density, surface wave resonators 1512 have a nominal duty factor but an area four times the reference area because the use of a series cascade configuration to reduce the areal power density. In some instances, a use of a series cascade configuration for the resonators results in an areal power density significantly below a limit determined from experiments, simulations, or other calculations. In such cases, the duty factor and area may be increased and decreased, respectively, for a SAW resonator at the cost of raising the areal power density for a single resonator. However, when placed in a series cascade, the SAW resonators with higher duty factor and lower area will have an overall lower area and an areal power density below the limit. An example is depicted by SAW resonators 1514. SAW resonators 1514 have a 25% higher duty factor and a reduced area compared to the nominal duty factor in SAW resonators 1512. As a result, a series cascade configuration of SAW resonators 1514 has an area less than the SAW resonators 1512—2.5 times the reference area compared to 4 times the reference area.

When the areal power density of a SAW resonator is above, but sufficiently close, to a known limit, then a series cascade configuration may be unnecessary. By reducing the duty factor and increasing the area of a SAW resonator, the areal power density may be reduced below a known limit. An example is depicted by SAW resonator 1516. SAW resonator 1516 has duty factor 25% lower than the nominal duty factor and an area 1.5 times the reference area. As a result, SAW resonator 1516 has an area power density lower than the known limit. An additional benefit of a reduced duty factor is improved temperature coefficient of frequency, i.e., less variation across different thermal loads. SAW resonators 1512, 1514, 1516 may be examples of resonators whose areal power densities have been optimized (“DPD Optimum” in FIGS. 8-13).

Surface acoustic wave resonator 1500 provides a reference area and nominal duty factor for comparison with SAW resonators that are not power limiting, i.e., areal power density is not a concern. When areal power density is not a concern, then resonators can be configured to have reduced area through an increase in the duty factor. An example is depicted by SAW resonator 1522. SAW resonator 1522 has a duty factor 25% higher than the nominal duty factor and an area that is 0.75 times the reference area. SAW resonator 1522 may be an example of a resonator whose duty factor has been maximized (DF Max. in FIGS. 8-13).

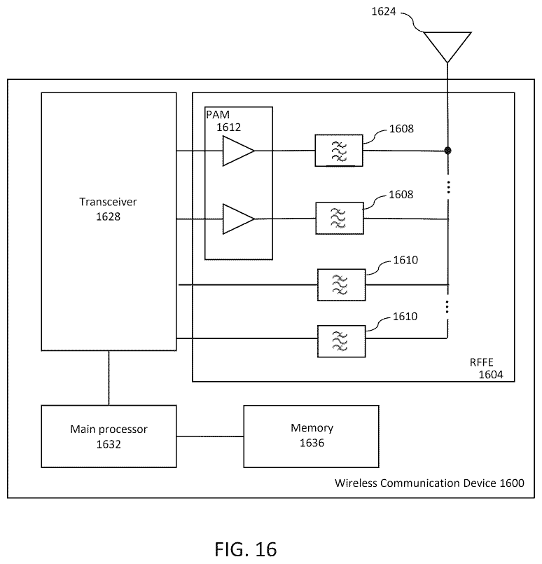

FIG. 16 is block diagram of a wireless communication device 1600 including one or more SAW devices/filters, according to aspects of the present disclosure. A block diagram of an example wireless communication device 1600 is illustrated in FIG. 16 in accordance with various example embodiments. However, it should be noted that the example embodiments of a temperature compensated SAW devices/filters described herein, and apparatuses including such temperature compensated SAW devices/filters may be incorporated into various other apparatuses and/or systems. The wireless communication device 1600, may include any number of different SAW transmission filters 1608 (e.g., similar to 810, 910, 1010, 1110, 1210, 1310 in FIGS. 8-13) and/or SAW receiver filters 1610 (e.g., similar to 815, 915, 1015, 1115, 1215 in FIGS. 8-13). Wireless communication device may include radio frequency front end (RFFE) circuitry 1604, which may include transmission filters 1608, receiver filters 1610, and power amplifier module 1612.

The SAW filters 1608, 1610 may operate to filter frequencies of transmitted/received signals. Each of the SAW filters 1608, 1610 may include any number of resonators in various arrangements and/or configurations, e.g., as depicted in FIGS. 8-13 and described herein. In some embodiments, the SAW filters 1608 may be integrated with an antenna switch module (ASM, not shown). SAW filters 1608 may additionally or alternatively be disposed external to the ASM. The ASM may include, a switch coupled with an antenna 1624. The switch may selectively couple the antenna 1624 with various transmit or receive chains. While the wireless communication device 1600 is described with transmitting and receiving capabilities, other embodiments may include devices with only transmitting or only receiving capabilities.

In some embodiments, the antenna 1624 may include one or more directional and/or omnidirectional antennas, including, for example, a dipole antenna, a monopole antenna, a patch antenna, a loop antenna, a microstrip antenna and/or any other type of antenna suitable for over the air (OTA) transmission/reception of RF signals. In some embodiments, the wireless communication device 1600 may include a duplexer or multiplexer comprising one or more SAW filters 1608, 1610. In such embodiments, the transceiver 1628 may additionally/alternatively include a receiver for receiving RF signals, communicating incoming data, from the duplexer/multiplexer and antenna 1624. In such embodiments, the transceiver 1628 may additionally/alternatively include a transmitter for transmitting RF signals, communicating outgoing data, through the duplexer/multiplexer and antenna 1624. Furthermore, the transmitter and the receiver may include one or more SAW filters 1608, 1610, respectively.

The power amplifier module (PAM) 1612 may be a multi-modal, multi-band power amplifier (MMPA) that integrates a plurality of power amplifiers and control logic to support various frequency bands and communication modes. The PAM 1612 may amplify RF signals received from a transceiver 1628 for transmission by the antenna 1624.

The transceiver 1628 may receive outgoing data (e.g., voice data, web data, e-mail, signaling data, etc.) from a main processor 1632, may generate RF signals to represent the outgoing data, and provide the RF signals to the radio frequency front end (RFFE) circuitry 1604. In some embodiments, the transceiver 1628 may generate the RF signals using orthogonal frequency-division multiplexing modulation. The transceiver 1628 may also receive an incoming OTA signal from the antenna 1624 through the RFFE 1604. The transceiver 1628 may process and send the incoming signal to the main processor 1632 for further processing.

The main processor 1632 may execute a basic operating system program, stored in memory 1636, in order to control the overall operation of the wireless communication device 1600. For example, the main processor 1632 may control the reception of signals and the transmission of signals by transceiver 1628. The main processor 1632 may be capable of executing other processes and programs resident in the memory 1636 and may move data into or out of memory 1636, as desired by an executing process.

In various embodiments, the wireless communication device 1600 may be, but is not limited to, a mobile cellular phone, a desktop personal computer (PC), a laptop PC, a tablet PC, a paging device, a personal digital assistant, a text-messaging device, a laptop computer, a wearable computing device, a subscriber station, an access point, a radar, a satellite communication device, and/or any other device capable of wirelessly transmitting/receiving RF signals.

Those skilled in the art will recognize that the wireless communication device 1600 is given by way of example and that, for simplicity and clarity, only so much of the construction and operation of the wireless communication device 1600 as is necessary for an understanding of the embodiments is shown and described. Various embodiments contemplate any suitable component or combination of components performing any suitable tasks in association with wireless communication device 1600, according to particular needs. Moreover, it is understood that the wireless communication device 1600 should not be construed to limit the types of devices in which embodiments may be implemented.

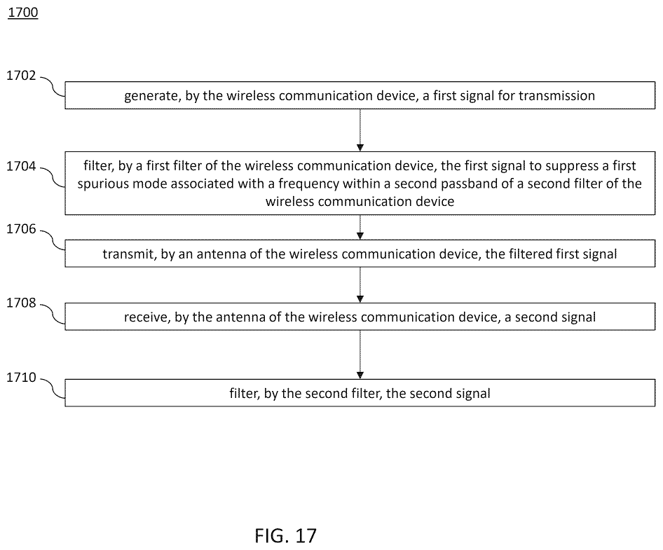

FIG. 17 depicts a method performed by a wireless communication device, according to some aspects of the present disclosure. For example, method 1700 may be performed by wireless communication device 1600 depicted in FIG. 16 and described above. Method 1700 is merely an example, and is not intended to limit the present disclosure. Additional operations can be provided before, during, and after the method 1700, and some operations described can be replaced, eliminated, or reordered for some embodiments of FIGS. 1-16. For case of illustration, FIG. 17 is described in connection with FIGS. 1-16.

At step 1702, a wireless communication device (e.g., wireless communication device 1600 in FIG. 16) generates a first signal for transmission. For example, the first signal may be the signal prepared other components of the wireless communication device 1600, e.g., one or more of the processor 1632, transceiver 1628, or PAM 1612 in FIG. 16. First signal may include the encoded information of a message to be transmitted to another device.

At step 1704, a first filter (e.g., transmission filter 1608 in FIG. 16) with a first passband (e.g., the transmission passband of the transmission filter 1608) of the wireless communication device filters the first signal to suppress a spurious mode associated with a frequency within a second passband (e.g., the receiver passband of receiver filter 1610 in FIG. 16) of a second filter (e.g., receiver filter 1610 in FIG. 16) of the wireless communication device. In some embodiments, the first filter may include a first plurality of acoustic wave resonators, e.g., the series and shunt resonators of transmission filters 810, 910, 1010, 1110, 1210, where each of the series and shunt resonators has a duty factor as indicated in FIGS. 8-12.

At step 1706, an antenna (e.g., antenna 1624 in FIG. 16) of the wireless communication device transmits the filtered first signal, i.e., the signal resulting from the filtering performed in step 1704.

At step 1708, the antenna of the wireless communication device receives a second signal. For example, the second signal may be a signal transmitting by another device or station in communication with the wireless communication device 1600.

At step 1710, the second filter (e.g., receiver filter 1610 in FIG. 16) filters the second signal. In some embodiments, the second filter may include a second plurality of acoustic wave resonators, e.g., the series and shunt resonators of receiver filters 815, 915, 1015, 1115, 1215, where each of the series and shunt resonators has a duty factor as indicated in FIGS. 8-12.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

What is claimed is:

1. An acoustic wave device comprising:
a piezoelectric substrate having a surface to support an acoustic wave;
a first filter disposed on the piezoelectric substrate, wherein the first filter comprises a first plurality of acoustic wave resonators, wherein the first plurality of acoustic wave resonators are associated with a first one or more duty factors; and
a second filter disposed on the piezoelectric substrate and electrically connected to the first filter, wherein the second filter comprises a second plurality of acoustic wave resonators, wherein the second plurality of acoustic wave resonators are associated with a second one or more duty factors,
wherein a first resonator duty factor in the first one or more duty factors or the second one or more duty factors is configured to suppress a spurious mode associated with a frequency within a first passband of the first filter or a second passband of the second filter.

2. The acoustic wave device of claim 1,
wherein the first filter comprises a transmission filter and the second filter comprises a receiver filter,
wherein a transmission passband of the transmission filter includes a first center frequency,
wherein a receiver passband of the receiver filter includes a second center frequency, and
wherein the first center frequency and second center frequency are different.

3. The acoustic wave device of claim 2,
wherein the transmission filter is in a ladder configuration,
wherein the first plurality of acoustic wave resonators includes a first plurality of shunt resonators and a first plurality of series resonators, and
wherein the second plurality of acoustic wave resonators includes a second plurality of shunt resonators and a second plurality of series resonators.

4. The acoustic wave device of claim 1, wherein a second resonator duty factor in the first one or more duty factors or the second one or more duty factors is configured to optimize the areal power density within the acoustic wave device.

5. The acoustic wave device of claim 1, wherein a third resonator duty factor in the first one or more duty factors or the second one or more duty factors is maximized.

6. The acoustic wave device of claim 1, wherein the first one or more duty factors comprises a first duty factor and a second duty factor, wherein the second one or more duty factors comprises a third duty factor and a fourth duty factor, wherein the first duty factor and the second duty factor are distinct, and wherein the third duty factor and fourth duty factor are distinct.

7. The acoustic wave device of claim 3, wherein a duty factor of the first plurality of shunt resonators and the second plurality of shunt resonators is configured to minimize the spurious mode associated with the first plurality of shunt resonators and the second plurality of shunt resonators.

8. The acoustic wave device of claim 1, wherein the first resonator duty factor is between 40%-50%.

9. The acoustic wave device of claim 8, wherein a second resonator duty factor in the first one or more duty factors or the second one or more duty factors is between 80%-95%.

10. The acoustic wave device of claim 1, wherein at least one duty factor in the first one or more duty factors is distinct from each duty factor in the second one or more duty factors.

11. A wireless communication device, comprising:
a radio frequency front end (RFFE) circuitry comprising:
an acoustic wave device comprising:
a piezoelectric substrate having a surface to support an acoustic wave; and
a first filter disposed on the piezoelectric substrate, wherein the first filter comprises a first plurality of acoustic wave resonators, wherein the first plurality of acoustic wave resonators are associated with a first one or more duty factors; and
a second filter disposed on the piezoelectric substrate and electrically connected to the first filter, wherein the second filter comprises a second plurality of acoustic wave resonators, wherein the second plurality of acoustic wave resonators are associated with a second one or more duty factors,
wherein a first resonator duty factor in the first one or more duty factors or the second one or more duty factors is configured to suppress a spurious mode associated with a frequency within a first passband of the first filter or a second passband of the second filter.

12. The wireless communication device of claim 11,
wherein the first filter comprises a transmission filter and the second filter comprises a receiver filter,
wherein a transmission passband of the transmission filter includes a first center frequency,
wherein a receiver passband of the receiver filter includes a second center frequency, and
wherein the first center frequency and second center frequency are different.

13. The wireless communication device of claim 12,
wherein the transmission filter is in a ladder configuration,
wherein the first plurality of acoustic wave resonators includes a first plurality of shunt resonators and a first plurality of series resonators, and
wherein the second plurality of acoustic wave resonators includes a second plurality of shunt resonators and a second plurality of series resonators.

14. The wireless communication device of claim 11, wherein a second resonator duty factor in the first one or more duty factors or the second one or more duty factors is configured to optimize the areal power density within the acoustic wave device.

15. The wireless communication device of claim 11, wherein a third resonator duty factor in the first one or more duty factors or the second one or more duty factors is maximized.

16. The wireless communication device of claim 11, wherein the first one or more duty factors comprises a first duty factor and a second duty factor, wherein the second one or more duty factors comprises a third duty factor and a fourth duty factor, wherein the first duty factor and the second duty factor are distinct, and wherein the third duty factor and fourth duty factor are distinct.

17. The wireless communication device of claim 13, wherein a duty factor of the first plurality of shunt resonators and the second plurality of shunt resonators is configured to minimize the spurious mode associated with the first plurality of shunt resonators and the second plurality of shunt resonators.

18. The wireless communication device of claim 11, wherein the first resonator duty factor is between 40%-50%.

19. The wireless communication device of claim 18, wherein a second resonator duty factor in the first one or more duty factors or the second one or more duty factors is between 80%-95%.

20. A method performed by a wireless communication device, comprising:
generating, by the wireless communication device, a first signal for transmission;
filtering, by a first filter with a first passband of the wireless communication device, the first signal to suppress a spurious mode associated with a frequency within a second passband of a second filter of the wireless communication device;
transmitting, by an antenna of the wireless communication device, the filtered first signal;
receiving, by the antenna of the wireless communication device, a second signal; and
filtering, by the second filter, the second signal,
wherein the first filter comprises a first plurality of acoustic wave resonators, wherein the first plurality of acoustic wave resonators are associated with a first one or more duty factors, and
wherein the second filter is electrically connected to the first filter, wherein the second filter comprises a second plurality of acoustic wave resonators, wherein the second plurality of acoustic wave resonators are associated with a second one or more duty factors.
